(19) United States
(12) Patent Application Publication
(10) Pub. No.: US 2016/0109503 A1
(43) Pub. Date: Apr. 21, 2016

(54) JIG, MANUFACTURING METHOD THEREOF AND TEST METHOD

(71) Applicant: KABUSHIKI KAISHA TOSHIBA, Minato-ku (JP)

(72) Inventors: Hirofumi ONO, Kuwana (JP); Hiroaki MURAKAMI, Yokkaichi (JP)

(73) Assignee: KABUSHIKI KAISHA TOSHIBA, Minato-ku (JP)

(21) Appl. No.: 14/643,369

(22) Filed: Mar. 10, 2015

Related U.S. Application Data
(60) Provisional application No. 62/064,001, filed on Oct. 15, 2014.

(51) Int. Cl. G01R 31/26; H01L 21/66

(52) U.S. Cl. CPC G01R 31/2601; H01L 22/12; H01L 22/32

(57) ABSTRACT

In accordance with an embodiment, a jig includes a substrate, a plurality of wiring lines on the substrate, and an electrode on one end of each of the wiring lines. The electrode is located so as to correspond to a location of an electrode of an external semiconductor chip and includes gold (Au), silver (Ag), aluminum (Al), tin (Sn), or indium (In).

### CROSS REFERENCE TO RELATED APPLICATIONS

This application is based upon and claims the benefit of U.S. provisional Application No. 62/064,001, filed on Oct. 15, 2014, the entire contents of which are incorporated herein by reference.

### FIELD

Embodiments described herein relate generally to a jig, a manufacturing method thereof, and a test method.

### BACKGROUND

In general, in a test of a semiconductor device, a probe needle abuts on an electrode of the semiconductor device, or a wire is bonded to the electrode. A test signal is input from a tester via the probe needle and the wire.

However, some products are not robust and are damaged by the above methods, and may therefore be difficult to test.

### BRIEF DESCRIPTION OF THE DRAWINGS

In the accompanying drawings:

FIG. 1 is an example of a perspective view showing a jig according to one embodiment;

FIG. 2 is an example of a perspective view illustrating a manufacturing method of a jig according to one embodiment; and

FIG. 3A to FIG. 9 are examples of perspective views illustrating a test method according to one embodiment.

### DETAILED DESCRIPTION

In accordance with an embodiment, a jig includes a substrate, a plurality of wiring lines on the substrate, and an electrode on one end of aluminum (Al), tin (Sn), or indium (In).

Embodiments will now be explained with reference to the accompanying drawings. Like components are provided with like reference signs throughout the drawings and repeated descriptions thereof are appropriately omitted. It is to be noted that the accompanying drawings illustrate the invention and assist in the understanding of the illustration and that the shapes, dimensions, and ratios and so on in each of the drawings may be different in some parts from those in an actual apparatus.

In the specification of the present application, a “top surface” refers to a surface in which an electrode is formed among surfaces of a test piece, and a “rear surface” refers to a surface opposite to the top surface among the surfaces of the test piece. In the specification of the present application, “stacking” not only includes stacking layers in contact with each other but also includes staking layers with another layer interposed in between. “Providing on” not only includes providing a layer in direct contact with a layer but also includes providing a layer on a layer with another layer interposed in between. Moreover, terms indicating upward, downward, and other directions in the explanation in the specification of the present application mean relative directions when a later-described electrode formation surface of the test piece faces upward. Therefore, the directions may be different from actual directions based on gravitational acceleration directions.

(1) Jig

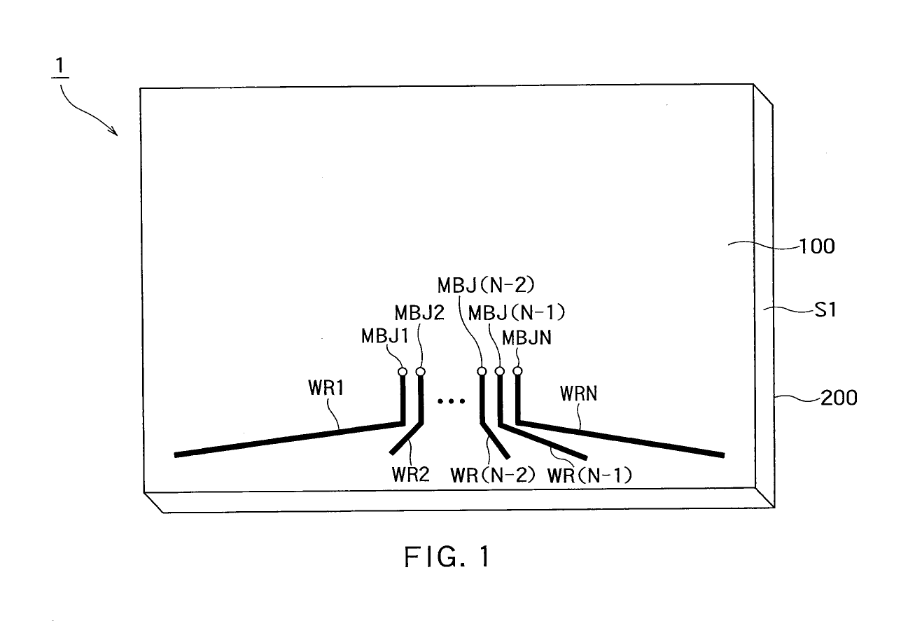

FIG. 1 is an example of a perspective view showing a jig according to one embodiment.

A jig 1 according to the present embodiment is a jig for testing a semiconductor chip, and includes a substrate S1, wiring lines WR1, WR2, . . . , WR(N−2), WR(N−1), and WRN (N is a natural number equal to or more than 2), and micro-bumps MBJ1, MBJ2, . . . , MBJ(N−2), MBJ(N−1), and MBJN (N is a natural number equal to or more than 2).

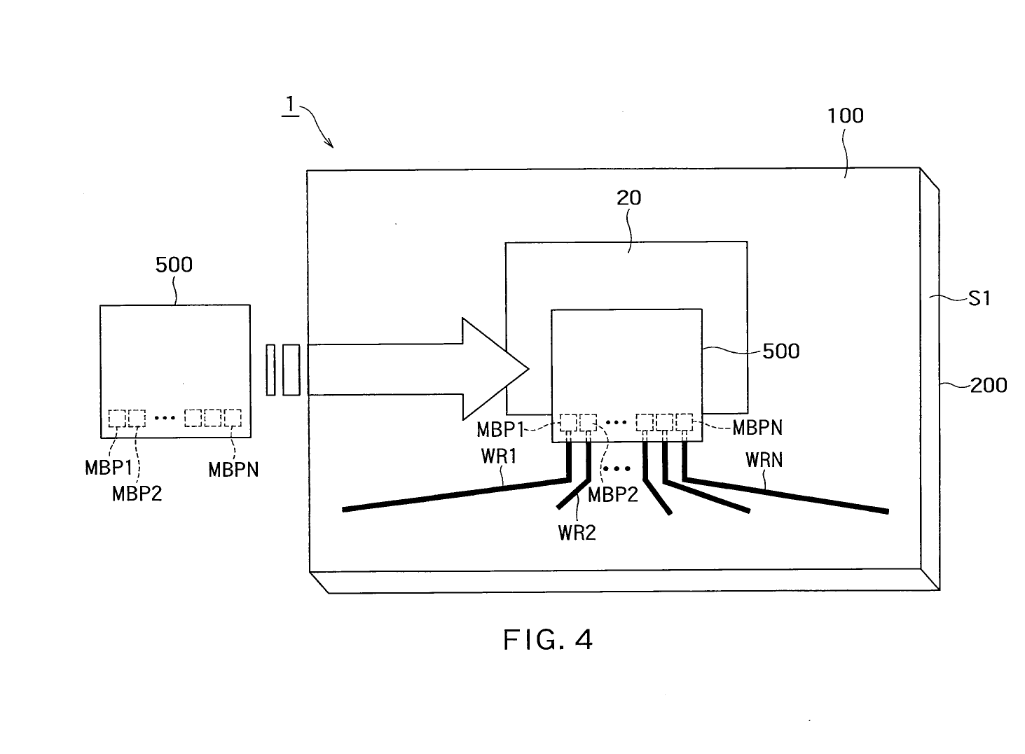

The material, composition, and others of the substrate S1 are not specifically limited. However, when a test using light is conducted as will be described later, it is preferable to use a translucent glass substrate or silicon substrate. Although the thickness of the substrate S1 is not specifically limited, it is preferable that the substrate S1 has such strength as to be able to ensure planarity during the attachment of a test piece (see the sign 500 in FIG. 4). In the present embodiment, the thickness of the substrate S1 is about 1 mm.

The wiring lines WR1, WR2, . . . , WR(N−2), WR(N−1), and WRN (hereinafter briefly referred to as “WRJ1 to WRJN”) are formed by a conductive material on a surface 100 facing the test piece among surfaces of the substrate S1.

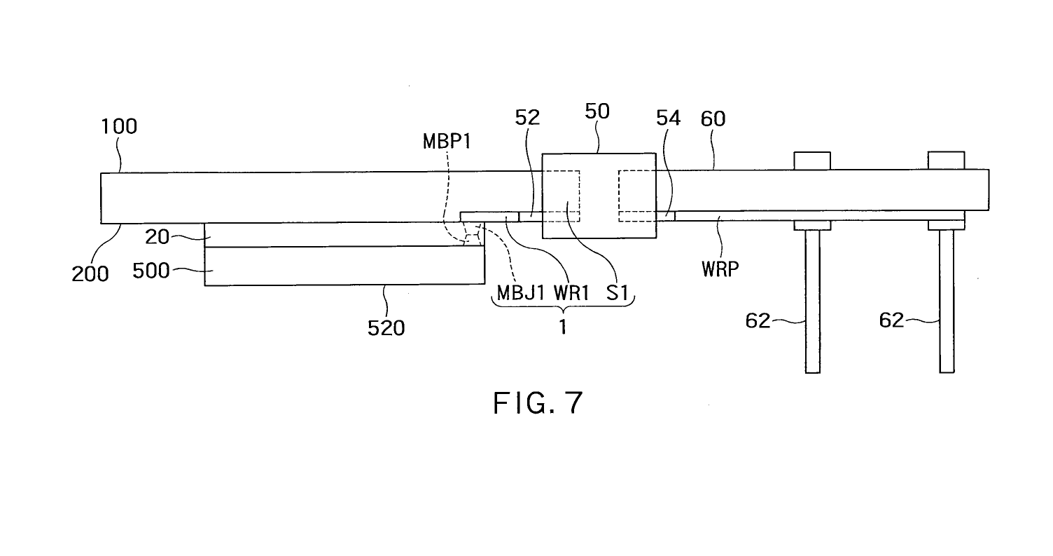

One of two ends of each wiring line WRJ on the peripheral edge side of the substrate S1 is terminated at a position corresponding to a pin 52 (see FIG. 7) of a later-described connector 50. The position of the other end of each wiring line WRJ (on the central side of the substrate S1) is previously adjusted to correspond to the position of each of micro-pads (see the signs MBP1 to MBPN in FIG. 4) of the test piece.

Each of the micro-bumps MBJ1, MBJ2, . . . , MBJ (N−2), MBJ (N−1), and MBJN (hereinafter briefly referred to as “MBJ1 to MBJN”) is provided on the other end of each of the above-mentioned wiring lines WRJ1 to WRJN (on the central side of the substrate S1). It is preferable that the micro-bumps MBJ1 to MBJN are made of a conductive material which is deformable at room temperature and that its hardness is such that the micro-bumps MBJ1 to MBJN can contact the micro-pads (see the signs MBP1 to MBPN in FIG. 4) with press force which does not change the electric properties of the test piece when the test piece is attached to the jig 1. A specific materials for the micro-bumps MBJ1 to MBJN may be, for example, gold (Au), silver (Ag), aluminum (Al), tin (Sn), or indium (In). Gold (Au) is particularly preferred.

The micro-bumps MBJ1 to MBJN are not particularly limited in size. In the present embodiment, each of the micro-bumps MBJ1 to MBJN is about 100 μm.

The jig according to at least one embodiment described above includes the micro-bumps MBJ1 to MBJN provided by a conductive material that is deformable at room temperature by slight press force which does not change the electric properties of the test piece. Therefore, the test piece can be attached in a testable manner without wire bonding. Consequently, it is possible to attach semiconductor devices susceptible to damage such as a product having a through silicon via (TSV) (hereinafter referred to as a “TSV product”) in a testable manner without extra labor.

In addition, the jig according to at least one embodiment described above includes the micro-bumps MBJ1 to MBJN that contact the electrode of the test piece, so that the less robust test piece can be tested without bonding.

Furthermore, in the jig according to at least one embodiment described above, the micro-bumps MBJ1 to MBJN are deformed by the above-mentioned slight press force, so that during attachment, the micro-bumps MBJ1 to MBJN contact bumps of the test piece in broad surface contact rather than point contact while the press force is absorbed. As a result, contact resistance is reduced, and an accurate test is possible.

Moreover, in the jig according to at least one embodiment described above, the micro-bumps MBJ1 to MBJN are deformed by the above-mentioned slight press force, so that height variation which may occur during the attachment of the test piece can be absorbed.

(2) Manufacturing Method of Jig

A manufacturing method of the jig 1 shown in FIG. 1 is described as a manufacturing method of a jig according to one embodiment by way of example.

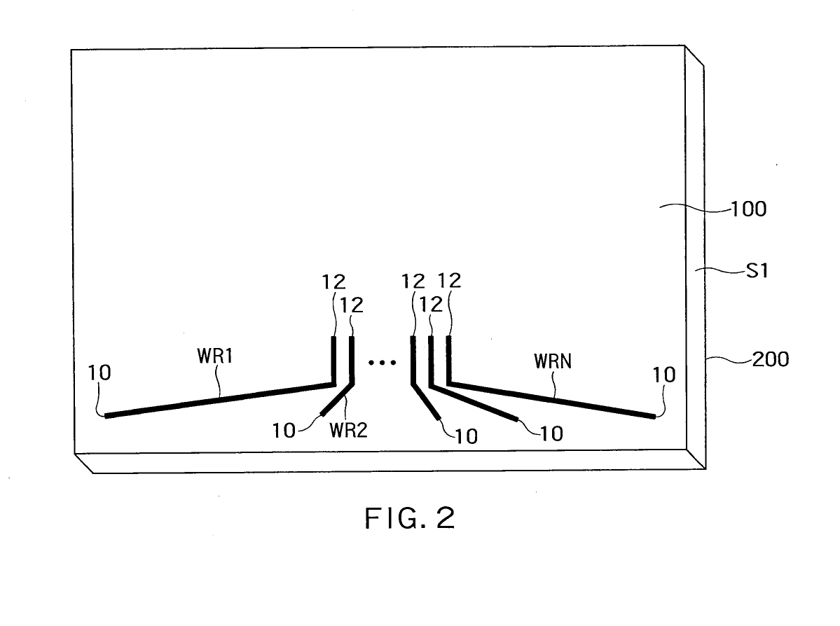

FIG. 2 is an example of a perspective view illustrating a manufacturing method of a jig according to the present embodiment.

First, a substrate S1 is prepared. In the present embodiment, a glass substrate having a thickness of about 1 mm is used.

Wiring lines WRJ1 to WRJN are then formed on a surface 100 facing a test piece among surfaces of the substrate S1 by existing technology. The material of the wiring lines is not specifically limited as long as it is a conductive material. However, it is preferable to use the same material as micro-bumps MBJ1 to MBJN to be formed later. In the present embodiment, the wiring lines WRJ1 to WRJN are formed by the use of gold (Au).

The number and shapes of wiring patterns are independently designed for each test piece. However, one end 10 on the peripheral edge side is designed to be terminated at a position corresponding to a pin 52 (see FIG. 7) of a later-described connector 50, and the other end 12 located on the central side of the substrate is designed to correspond to the locations of the micro-pads (see the signs MBP1 to MBPN in FIG. 4) of the test piece (see the sign 500 in FIG. 4).

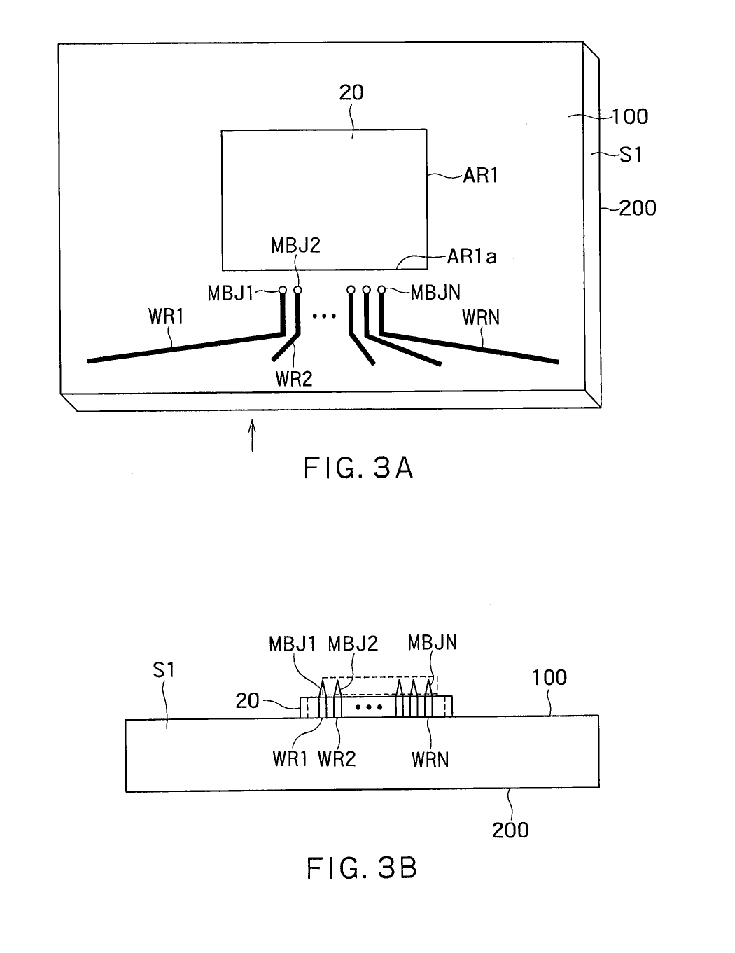

The micro-bumps MBJ1 to MBJN having a diameter of, for example, about 100 μm are then formed in the other ends 12 of the wiring lines WRJ1 to WRJN by, for example, a superfine inkjet method (see FIG. 3B). Thus, the jig 1 shown in FIG. 1 is provided.

It is preferable that the material of the micro-bumps MBJ1 to MBJN is a conductive material that is deformable at room temperature and that the material has hardness such that the micro-bumps MBJ1 to MBJN can contact the micro-pads of the test piece with press force which does not change the electric properties of the test piece. A specific material for the micro-bumps MBJ1 to MBJN may be, for example, gold (Au), silver (Ag), aluminum (Al), tin (Sn), or indium (In). In the present embodiment, gold (Au) is used.

According to the manufacturing method in at least one embodiment described above, it is possible to manufacture a jig which provides the above-described advantageous effects in a simple manner using existing technology.

(3) Test Method

A test method of the test piece using the above-mentioned jig 1 is described as one embodiment with reference to FIG. 3A to FIG. 9. In the present embodiment, the semiconductor chip 500 which is a TSV product shown in FIG. 4 is described as the test piece by way of example. However, it should be understood that the test piece is not limited to the semiconductor chip 500, and any semiconductor device having an electrode that can contact the micro-bumps MBJ1 to MBJN is applicable.

(a) Manufacture of Jig

First, the jig 1 shown in FIG. 1 is prepared by the manufacturing method according to the embodiment described above.

(b) Attachment of Chip

The semiconductor chip 500 is then attached to the jig 1. In the present embodiment, wax is used as a fixing agent.

More specifically, as shown in FIG. 3A, wax 20 having a relatively low melting point, for example, a melting point of about 60° C. is applied to an area AR1 corresponding to the shape of a surface to be attached to the jig 1 among surfaces of the semiconductor chip 500 in the surface 100 of the substrate S1. In this instance, a part AR1a of the peripheral edge of the area AR1 facing the micro-bumps MBJ1 to MBJN is located apart from the micro-bumps MBJ1 to MBJN at a distance that allows a sufficient margin between the part AR1a and the micro-bumps MBJ1 to MBJN so that the wax 20 will not inhibit electric connection between the micro-bumps MBJ1 to MBJN of the jig 1 and the micro-pads MBP1 to MBPN (N is a natural number equal to or more than 2) (see FIG. 4) of the semiconductor chip 500. A front view (view from the direction indicated by an arrow in FIG. 3A) of this state is shown in FIG. 3B.

As shown in FIG. 4, the semiconductor chip 500 is moved in such a manner that the top surface of the semiconductor chip 500 faces the surface 100 of the substrate S1, and the semiconductor chip 500 is attached to the jig 1 by pressure after the micro-pads MBP1 to MBPN (N is a natural number equal to or more than 2) are aligned with the micro-bumps MBJ1 to MBJN of the jig 1.

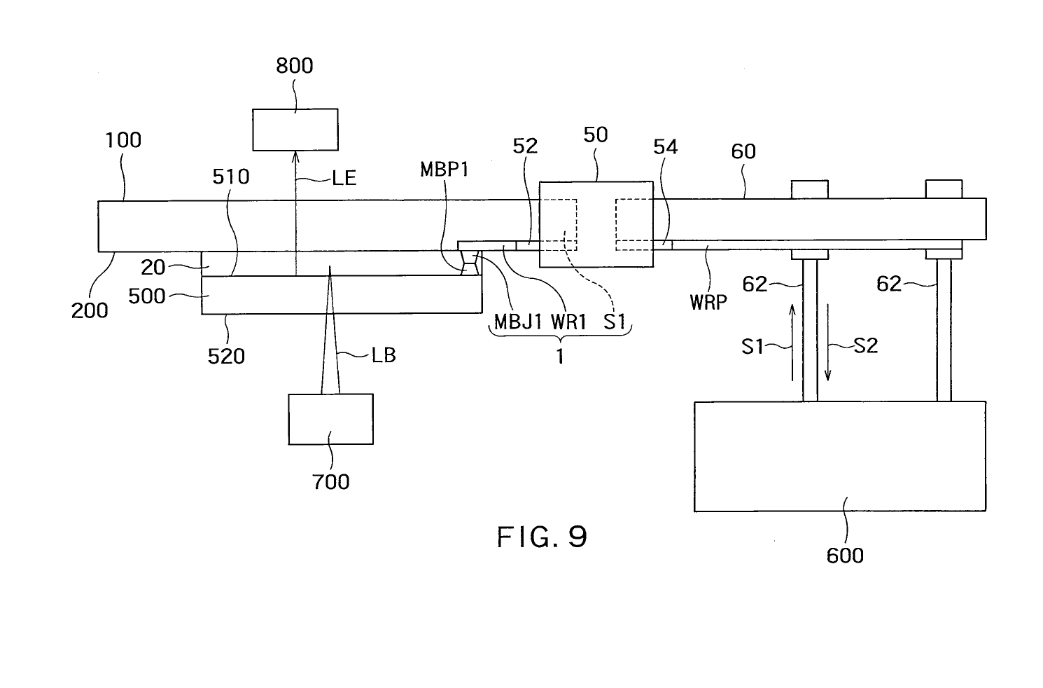

The press force in this case is kept at strength which does not change the electric properties of the semiconductor chip 500. Since the micro-bumps MBJ1 to MBJN of the jig 1 are made of gold (Au) in the present embodiment, the tips of the micro-bumps MBJ1 to MBJN are crushed by this press force so that the micro-bumps MBJ1 to MBJN contact the micro-pads MBP1 to MBPN of the semiconductor chip 500 in a spread state sufficient for low-resistance transmission of a test signal (see the sign S1 in FIG. 9).

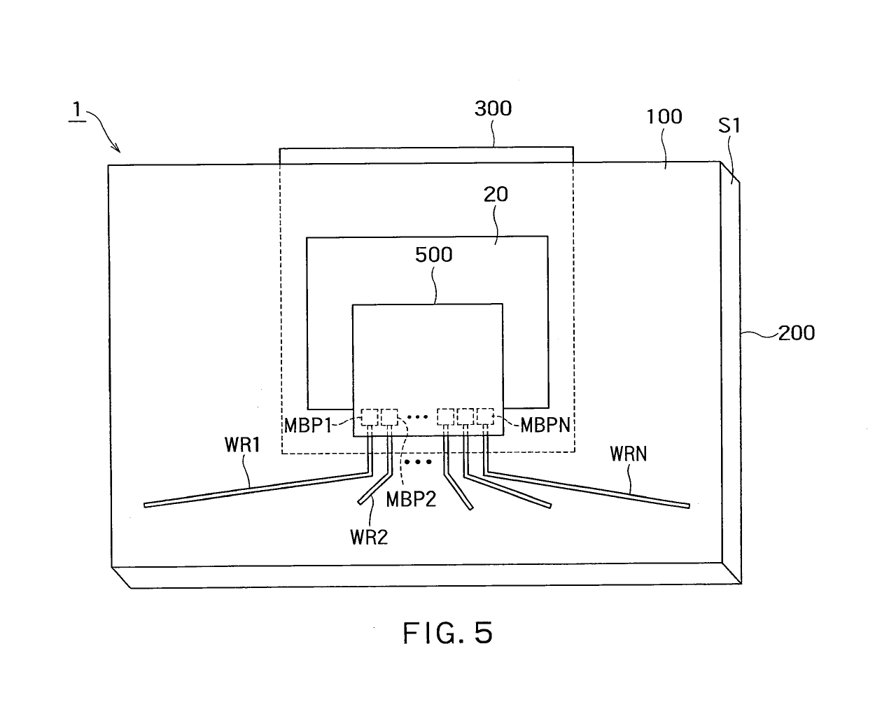

The temperature of the wax 20 is raised to about 60° C. while the press force for attachment is maintained, and then cooling is performed. For example, as shown in FIG. 5, a Peltier element 300 is put in abutment with a rear surface 200 of the substrate S1 opposite to the top surface 100, and the direction of an electric current is reversed immediately after the temperature has been raised to about 60° C. to perform cooling at once. As a result, the wax 20 which has once melted and filled the space between the top surface 100 of the substrate S1 and the top surface 100 of the semiconductor chip 500 is solidified, and the semiconductor chip 500 is attached to the jig 1 accordingly. Since the micro-pads MBP1 to MBPN and the micro-bumps MBJ1 to MBJN have already come into broad surface contact, the wax 20 does not infiltrate into the interface therebetween.

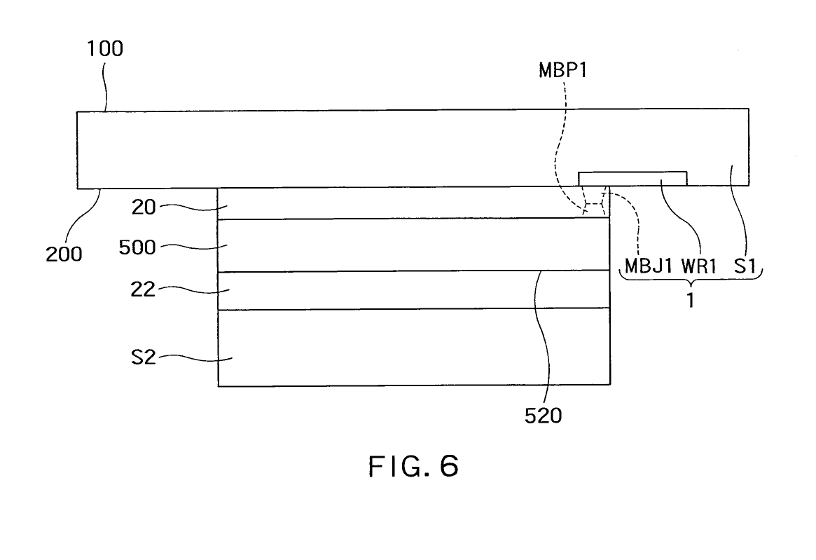

When the size of the semiconductor chip 500 is so large as to cause warping and bending, it is preferable that a support substrate S2 is previously attached to the semiconductor chip 500 from the side of a rear surface 520 of the semiconductor chip 500 via, for example, wax 22 as shown in a sectional view of FIG. 6 before the semiconductor chip 500 is attached to the jig 1. In this way, a test can be conducted in a stable state, and it is possible to prevent applied light (see the sign LB in FIG. 9) from being out of focus in a test that uses light.

In the present embodiment, the support substrate S2 corresponds to, for example, a second substrate, and the substrate S1 corresponds to, for example, a first substrate.

(c) Connection to Tester

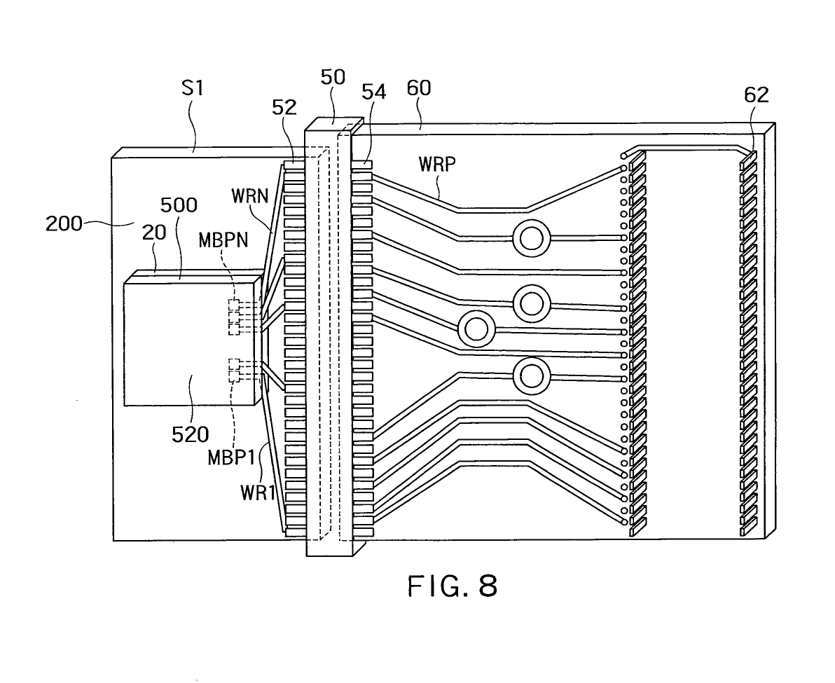

As shown in FIG. 7, the jig 1 to which the semiconductor chip 500 is attached is then coupled to a print-circuit board 60 via the connector 50. The print-circuit board 60 is provided with connection terminals 62 for electric connection to test equipment (see the sign 600 in FIG. 9). Thus, the micro-pads MBP1 to MBPN of the semiconductor chip 500 are connected to the test equipment via the micro-bumps MBJ1 to MBJN of the jig 1, part of the connector pin 52, part of a connector pin 54, a wiring line WRP of the print-circuit board 60, and part of the connection terminals 62. An example of a perspective view (seen from the rear surface 520 of the semiconductor chip 500) in this state is shown in FIG. 8.

(d) Running of Test

As shown in FIG. 9, the semiconductor chip 500 is connected to the test equipment 600 by connecting the connection terminals 62 of the print-circuit board 60 to the test equipment 600.

Other auxiliary equipment such as a light application unit 700 which emits laser beam LB and applies the laser beam LB to the semiconductor chip 500, and a light emission image pickup unit 800 which detects the light generated from the semiconductor chip 500 (in the case of a light emitting element) and acquires a light emission image are then set in accordance with the test contents, and the test of the semiconductor chip 500 is started.

In the present embodiment, an optical beam induced resistance change (OBIRCH) method and a photon emission microscope (PEM) are described by way of example. However, the present invention is not limited thereto, and is applicable to tests in general which input a test signal and analyze a reply signal.

i) Analysis by OBIRCH

First, for example, a constant voltage is applied to the semiconductor chip 500 from the test equipment 600 via the connection terminals 62, the print-circuit board 60, the connector 50, and the jig 1. In this state, the laser beam LB is emitted from the light application unit 700 and applied to the semiconductor chip 500 from the side of the rear surface 200 of the semiconductor chip 500, and a wiring line (not shown) in the semiconductor chip 500 is scanned with the laser beam LB. In this way, an electric current change made in the semiconductor chip 500 is detected by the test equipment 600 via, for example, the jig 1, and a resistance change caused by heat generated as a result of the application of the laser beam LB is monitored to narrow down a defective part of the semiconductor chip 500. The wiring layout of the semiconductor chip 500 may be referred to in order to narrow down the defective part. It is preferable that the laser beam LB is infrared light having a wavelength of 1.3 μm or less in the present example.

The semiconductor chip 500 is then locally fabricated by, for example, a focused ion beam (FIB), and a physical analysis is conducted by the use of observation means such as a scanning electron microscope (SEM) or a transmission electron microscope (TEM) to specify a defective part.

In the present embodiment, the substrate S1 of the jig 1 is made of a translucent material. Therefore, the laser beam is applied not exclusively from the side of the rear surface 520 of the semiconductor chip 500, and may be applied from the side of a top surface 510. Although the constant voltage is applied to the semiconductor chip 500 to monitor the electric current change in the above explanation, the present invention is not limited to this. For example, a constant current may be passed to monitor a voltage change.

ii) Analysis by PEM

A test signal S1 is applied from the test equipment 600 via the connection terminals 62, the print-circuit board 60, the connector 50, and the jig 1. In the present example, the test signal S1 is a signal to intentionally reproduce a situation in which an abnormal electric current runs.

Light LE generated from the semiconductor chip 500 in response to the input of the test signal S1 is detected by the light emission image pickup unit 800, and a light emission image is acquired. A defective part is narrowed down by, for example, checking the obtained light emission image against the wiring layout of the semiconductor chip 500. A physical analysis is then conducted by the use of TEM observation after FIB fabrication to specify a defective part, as in the analysis by the above-mentioned OBIRCH method.

In the present embodiment, the substrate S1 of the jig 1 is made of a translucent material. Therefore, the light emission image is acquired by the light emission image pickup unit 800 not exclusively from the side of the top surface 510 of the semiconductor chip 500, and may be acquired from the side of the rear surface 520.

(iii) Other Analyses

When the semiconductor chip 500 is a light emitting element, the test signal S1 is applied to the semiconductor chip 500 from the test equipment 600 via, for example, the jig 1, and the light LE generated from the semiconductor chip 500 is detected by a light receiving element such as the light emission image pickup unit 800, so that analyses of, for example, the presence of any abnormality and the specification of an abnormal part are possible.

(iv) Advantageous Effects of Present Embodiment

According to the test method in at least one embodiment described above, it is possible to readily run a test at low cost using a light and small-sized jig without using any large-scale equipment such as a probe card.

(4) Others

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A jig comprising:
substrate;
a plurality of wiring lines on the substrate; and
an electrode which is formed by a conductive material on one end of each of the wiring lines and is located so as to correspond to a location of an electrode of an external semiconductor chip,
wherein the electrode comprises gold (Au), silver (Ag), aluminum (Al), tin (Sn), or indium (In).

2. The jig of claim 1,
wherein the substrate is translucent.

3. The jig of claim 2,
wherein the substrate is translucent to infrared light.

4. The jig of claim 1,
wherein the substrate is a glass substrate or a silicon substrate.

5. A manufacturing method of a jig, the method comprising:
forming a plurality of wiring lines on the surface of a substrate; and
forming an electrode on one end of each of the wiring lines by using gold (Au), silver (Ag), aluminum (Al), tin (Sn), or indium (In),
wherein the jig is used in a test of a semiconductor chip.

6. The method of claim 5,
wherein the substrate is translucent.

7. The method of claim 6,
wherein the substrate is translucent to infrared light.

8. The method of claim 5,
wherein the substrate comprises glass or silicon.

9. A test method comprising:
preparing a jig, the jig comprising a first substrate, a plurality of wiring lines on the first substrate, and an electrode formed on one end of each of the wiring lines by using gold (Au), silver (Ag), aluminum (Al), tin (Sn), or indium (In), the electrode being provided to correspond to electrode arrangement of a semiconductor chip which is a test piece;
aligning so such a manner that an electrode of the semiconductor chip abuts on the electrode of the jig, attaching the test piece to the first substrate by using pressure thereby bringing the electrode of the semiconductor chip into contact with the electrode of the jig; and
applying a test signal to the semiconductor chip via the wiring lines, and detecting and analyzing an output signal from the semiconductor chip or light generated from the test piece.

10. The method of claim 9,
wherein attaching the test piece to the first substrate comprises
applying first wax to an area between the test piece and the first substrate, melting the first wax so that the first wax closely infiltrates into the part between the test piece and the first substrate, and then solidifying the first wax.

11. The method of claim 10,
wherein the melting temperature of the wax is controlled by a Peltier element.

12. The method of claim 9,
further comprising applying light instead of or together with the test signal.

13. The method of claim 12,
wherein the first substrate is translucent, and the light is applied to the test piece through the substrate.

14. The method of claim 9,
further comprising attaching a second substrate to the test piece via first wax on the side opposite to the side of the first substrate before attaching the test piece to the first substrate.
